(19) United States
(12) Patent Application Publication
(10) Pub. No.: US 2023/0361170 A1
(43) Pub. Date: Nov. 9, 2023

(54) SEMICONDUCTOR DEVICE AND SEMICONDUCTOR MODULE

(71) Applicant: Murata Manufacturing Co., Ltd., Kyoto (JP)

(72) Inventors: Fuminori MORISAWA, Kyoto (JP); Kazuhiro UEDA, Kyoto (JP)

(21) Appl. No.: 18/352,632

(22) Filed: Jul. 14, 2023

Related U.S. Application Data
(63) Continuation of application No. PCT/JP2022/001066, filed on Jan. 14, 2022.

(30) Foreign Application Priority Data
Jan. 15, 2021 (JP) 2021-005130

(51) Int. Cl. H01L 29/06; H01L 23/00; H01L 29/417; H01L 23/367

(52) U.S. Cl. CPC H01L 29/0619; H01L 24/05; H01L 24/06; H01L 24/13; H01L 24/14; H01L 24/16; H01L 29/41758; H01L 23/3675; H01L 2224/05553; H01L 2224/06152; H01L 2224/06519; H01L 2224/13014; H01L 2224/14152; H01L 2224/14519; H01L 2224/16235; H01L 2224/13024; H01L 2224/1411; H01L 2224/05548

(57) ABSTRACT

To provide a semiconductor device and a semiconductor module that are capable of improving a heat dissipation property in the semiconductor device including a heat generating element. A semiconductor device includes: a P-type semiconductor substrate, which has a main surface and a main surface opposed to the main surface; an N-type N well, which is provided on the main surface side of the semiconductor substrate; a unit field effect transistor, which is provided in the N well; a P-type heat dissipation guard ring region, which is provided on the main surface side of the semiconductor substrate on the outside of the N well in plan view of the semiconductor substrate; wiring, which is provided on the heat dissipation guard ring region; bump placement portions; and bumps.

### CROSS REFERENCE TO RELATED APPLICATION

This is a continuation of International Application No. PCT/JP2022/001066 filed on Jan. 14, 2022 which claims priority from Japanese Patent Application No. 2021-005130 filed on Jan. 15, 2021. The contents of these applications are incorporated herein by reference in their entireties.

### BACKGROUND ART

### Technical Field

The present disclosure relates to a semiconductor device and a semiconductor module.

In communication using mobile bodies such as cellular phones, a semiconductor module provided with a power amplifier circuit for power amplification is used. Patent Document 1 describes a semiconductor module that is provided with a heat dissipation member, which covers a semiconductor chip on which a power amplifier circuit is provided, so as to improve a heat dissipation property in the semiconductor module provided with the power amplifier circuit.
Patent Document 1: Japanese Unexamined Patent Application Publication No. 2005-228811

### BRIEF SUMMARY

In such a semiconductor module, heat generation occurs in a regulator circuit for supplying a power source voltage to a power amplifier circuit in addition to heat generation caused by the power amplifier circuit. The regulator circuit performs voltage conversion using a field effect transistor such as a MOSFET, for example. Heat generated in the field effect transistor during the voltage conversion affects the operation of the regulator circuit and affects the supply of the power supply voltage to the power amplifier circuit. As a result, the state of the power amplification in the power amplifier circuit may change and the operation of the semiconductor module may become unstable.

The present disclosure provides a semiconductor device and a semiconductor module that are capable of improving a heat dissipation property in the semiconductor device including a heat generating element.

A semiconductor device according to an aspect of the present disclosure includes: a semiconductor substrate that is a first conductive type and has a first main surface and a second main surface opposed to the first main surface; a first well that is a second conductive type and is provided on a first main surface side of the semiconductor substrate; a field effect transistor that is provided in the first well; a second well that is the first conductive type and is provided on the first main surface side of the semiconductor substrate in an outside of the first well in plan view of the semiconductor substrate; and a metal portion that is provided on the second well.

According to the present disclosure, a semiconductor device and a semiconductor module that are capable of improving a heat dissipation property in the semiconductor device including a heat generating element can be provided.

### BRIEF DESCRIPTION OF THE DRAWINGS

FIG. 1 is a block diagram of a semiconductor module according to a first embodiment.

FIG. 2 is a circuit diagram of a regulator circuit provided to the semiconductor module.

FIG. 3 is a plan view of a field effect transistor in the regulator circuit.

FIG. 4 is a sectional view taken along a FIG. 4 is a sectional view taken along a section line IV-IV in FIG. 3.

FIG. 5 is a layout diagram of a field effect transistor unit in a semiconductor device according to the first embodiment.

FIG. 6 is a sectional view taken along a section line VI-VI in FIG. 5.

FIG. 7 is a sectional view of the semiconductor module according to the first embodiment.

FIG. 8 is a sectional view taken along a section line VIII-VIII in FIG. 5.

FIG. 9 is another sectional view of the semiconductor module according to the first embodiment.

FIG. 10 is a layout diagram of a field effect transistor unit in a semiconductor device according to a second embodiment.

FIG. 11 is a sectional view taken along a section line XI-XI in FIG. 10.

FIG. 12 is a sectional view of a semiconductor module according to the second embodiment.

FIG. 13 is a layout diagram of a field effect transistor unit in a semiconductor device according to a third embodiment.

FIG. 14 is a sectional view taken along a section line XIV-XIV in FIG. 13.

FIG. 15 is a sectional view of a semiconductor module according to the third embodiment.

FIG. 16 is a layout diagram of a field effect transistor unit in a semiconductor device according to a fourth embodiment.

FIG. 17 is a sectional view taken along a section line XVII-XVII in FIG. 16.

FIG. 18 is a sectional view of a semiconductor module according to the fourth embodiment.

FIG. 19 is a layout diagram of a field effect transistor unit in a semiconductor device according to a fifth embodiment.

FIG. 20 is a sectional view taken along a section line XX-XX in FIG. 19.

FIG. 21 is a sectional view of a semiconductor module according to the fifth embodiment.

FIG. 22 is a schematic perspective view of a semiconductor module according to a sixth embodiment.

FIG. 23 is a sectional view of the semiconductor module according to the sixth embodiment.

### DETAILED DESCRIPTION

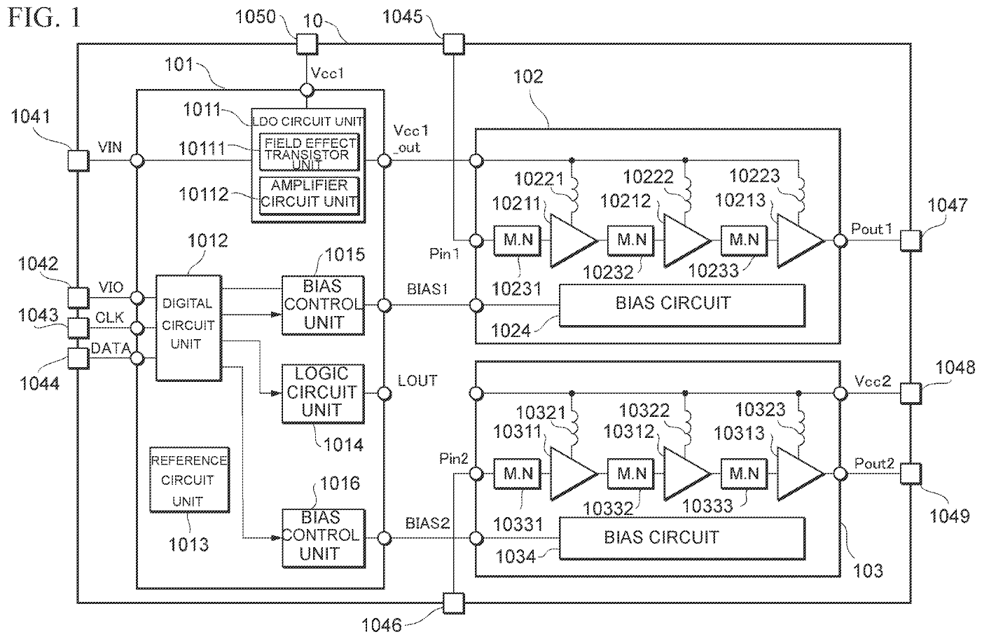

A first embodiment will be described. FIG. 1 illustrates a block diagram of a semiconductor module 10 according to the first embodiment. The semiconductor module 10 includes a semiconductor device 101, a semiconductor device 102, and a semiconductor device 103. The semiconductor module 10 further includes terminals 1041, 1042, 1043, 1044, 1045, 1046, 1047, 1048, 1049, and 1050.

In the semiconductor module 10, the semiconductor device 102 amplifies an input signal Pin1 inputted via the terminal 1045 and the semiconductor device 103 amplifies a signal Pin2 inputted via the terminal 1046. The semiconductor device 101 supplies a bias voltage to the semiconductor device 102, 103 and controls bias circuits 1024, 1034 of the semiconductor devices 102 and 103. The semiconductor device 102 and the semiconductor device 103 function as power amplifier circuits. The semiconductor device 101 functions as a circuit that controls the semiconductor devices 102 and 103 serving as power amplifier circuits. In the semiconductor module 10, the semiconductor devices 101, 102, and 103 are mounted on, for example, a laminated substrate.

The semiconductor device 101 includes an LDO circuit unit 1011, a digital circuit unit 1012, a reference circuit unit 1013, a logic circuit unit 1014, a bias control unit 1015, and a bias control unit 1016.

The LDO circuit unit 1011 supplies a power source voltage Vcc1_out to the semiconductor device 102 based on an input voltage VIN supplied from the terminal 1041 and a power source voltage Vcc1 supplied from the terminal 1050 to the semiconductor device 101. The LDO circuit unit 1011 includes a field effect transistor unit 10111 and an amplifier unit 10112. A circuit diagram of the LDO circuit unit 1011 will be described later.

The digital circuit unit 1012 supplies a signal to the logic circuit unit 1014 and the bias control units 1015 and 1016 based on a digital power source voltage VIO, which is inputted via the terminal 1042, a clock signal CLK, which is inputted via the terminal 1043, and a data signal DATA, which is inputted via the terminal 1044.

The reference circuit unit 1013 is a circuit that supplies a reference voltage to the LDO circuit unit 1011, the digital circuit unit 1012, the logic circuit unit 1014, and the bias control units 1015 and 1016.

The logic circuit unit 1014 outputs a digital signal LOUT such as a signal indicating a data transmission/reception state and a signal for controlling a band switching switch or the like, based on the signal from the digital circuit unit 1012.

The bias control unit 1015 transmits a bias control signal BIAS1 to the semiconductor device 102 based on the signal from the digital circuit unit 1012 so as to control the operation of the semiconductor device 102.

The bias control unit 1016 transmits a bias control signal BIAS2 to the semiconductor device 103 based on the signal from the digital circuit unit 1012 so as to control the operation of the semiconductor device 103.

The semiconductor device 102 includes amplifiers 10211, 10212, and 10213, inductors 10221, 10222, and 10223, matching elements 10231, 10232, and 10233, and a bias circuit 1024. The amplifiers and the matching elements are connected in series. To each of the amplifiers, the LDO circuit unit 1011 supplies the power source voltage Vcc1_out. The inductors 10221, 10222, and 10223 are connected to the respective amplifiers 10211, 10212, and 10213 as choke inductors. When a control signal for conducting power amplification is inputted into the bias circuit 1024, the semiconductor device 102 amplifies the input signal Pin1 and outputs an output signal Pout1 to the terminal 1047.

The semiconductor device 103 includes amplifiers 10311, 10312, and 10313, inductors 10321, 10322, and 10323, matching elements 10331, 10332, and 10333, and a bias circuit 1034. The semiconductor device 103 operates similarly to the semiconductor device 102.

The semiconductor device 103 is different from the semiconductor device 102 in that the semiconductor device 103 is supplied with a power source voltage Vcc2 via the terminal 1048.

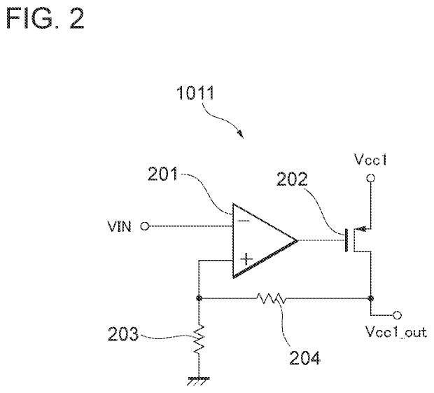

FIG. 2 illustrates the circuit diagram of the LDO circuit unit 1011. The LDO circuit unit 1011 includes an operational amplifier 201, a field effect transistor 202, and resistor elements 203 and 204.

VIN is inputted to an inverting input terminal of the operational amplifier 201. A non-inverting input terminal of the operational amplifier 201 is connected to ground via the resistor element 203 and also connected to a source of the field effect transistor 202 via the resistor element 204. An output terminal of the operational amplifier 201 is connected to a gate of the field effect transistor 202.

The power source voltage Vcc1 is supplied to a drain of the field effect transistor 202. The field effect transistor 202 outputs the power source voltage Vcc1_out from the source in response to a gate voltage inputted from the operational amplifier 201. In the present embodiment, the field effect transistor 202 is configured by connecting a plurality of field effect transistors by wiring. Individual field effect transistors constituting the field effect transistor 202 will be described as unit field effect transistors, in the present embodiment.

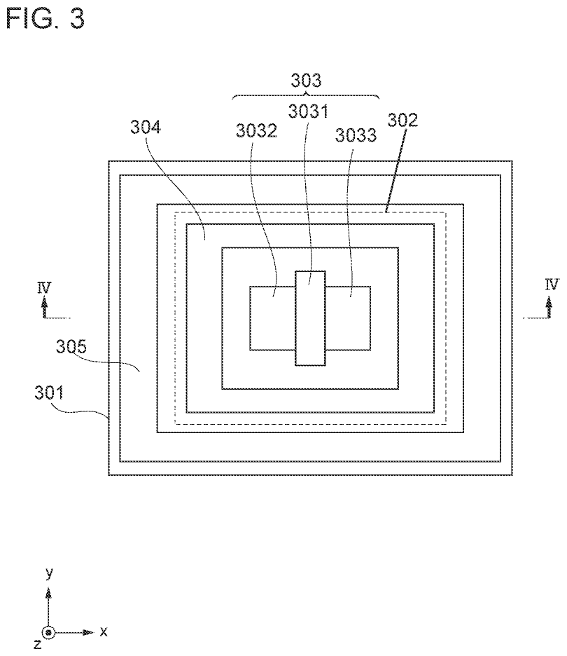

FIG. 3 illustrates a plan view of a semiconductor substrate 301 provided with a unit field effect transistor 303. Here, FIG. 3 does not illustrate a wiring layer and an insulating layer which will be described later. The unit field effect transistor 303 is provided on the semiconductor substrate 301 having a P-type (first conductive type) conductive property. An N well (first well) 302 having an N-type (second conductive type) conductive property is provided on the semiconductor substrate 301. The unit field effect transistor 303 is provided in the N well 302.

The unit field effect transistor 303 includes a gate electrode 3031, a source region 3032, and a drain region 3033. A back gate region 304 is provided so as to surround the unit field effect transistor 303. The back gate region 304 is a region that has the N-type conductive property and is provided so as to properly operate the unit field effect transistor 303.

A heat dissipation guard ring region (second well) 305 having the P-type conductive property is provided on the outside of the N well 302. More specifically, the heat dissipation guard ring region 305 is provided so as to surround the back gate region 304.

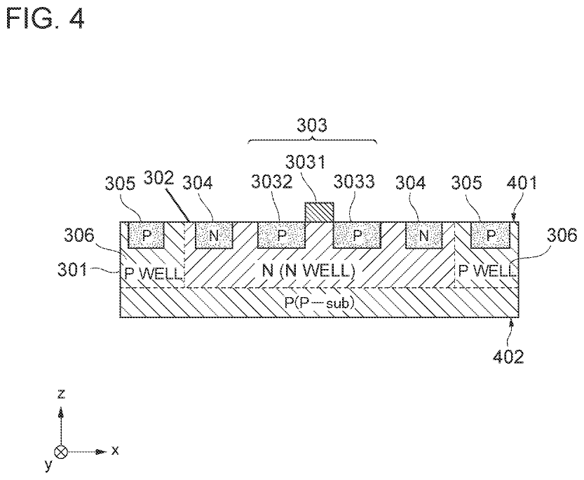

FIG. 4 is a sectional view of the semiconductor substrate 301 provided with the unit field effect transistor 303. The semiconductor substrate 301 has a main surface 401 (first main surface) along an xy plane and a main surface 402 (second main surface) opposed to the main surface 401. The N well 302 is provided on the main surface 401 side of the semiconductor substrate 301. The N well 302 is a semiconductor region that is formed by doping impurities into the semiconductor substrate 301 having the P-type conductive property. The N well 302 is a concave region, which is concave from the main surface 401 in a z-axis negative direction, in the semiconductor substrate 301.

The source region 3032 and the drain region 3033 are P-type regions that are formed in the N well 302 by doping impurities into the N well 302. The gate electrode 3031 is provided between the source region 3032 and the drain region 3033.

The back gate region 304 is a region that is formed by doping impurities into the N well 302 so as to provide a higher N-type conductive property than the N well 302.

The heat dissipation guard ring region 305 is a P-type region that is formed on the main surface 401 side of the semiconductor substrate 301 by doping impurities into the semiconductor substrate 301. The heat dissipation guard ring region 305 is a semiconductor region that is formed in a well shape on the main surface 401 side of the semiconductor substrate 301.

A P well 306 is a P-type region that is formed on the main surface 401 side of the semiconductor substrate 301 by doping impurities into the semiconductor substrate 301. The P well 306 is a region that has a higher P-type conductive property than a region on the main surface 402 side (P-sub in FIG. 4) of the semiconductor substrate 301. The depth of the P well 306 from the main surface 401 toward the main surface 402 is equal to the corresponding depth of the N well 302. The heat dissipation guard ring region 305 is a region that is formed by doping impurities into the P well 306 so as to provide a higher P-type conductive property than the P well 306. The heat dissipation guard ring region 305 and the P well 306 suppress polarity instability in the vicinity of the main surface 401.

Here, the polarities of the semiconductor substrate 301, the N well 302, the unit field effect transistor 303, the back gate region 304, the heat dissipation guard ring region 305, and the P well 306 may be reversed. That is, a P-type well may be formed in an N-type semiconductor substrate and a field effect transistor may be provided on this well. In this configuration, a region of the semiconductor substrate corresponding to the heat dissipation guard ring region 305 is a region that has a higher N-type conductive property than this semiconductor substrate.

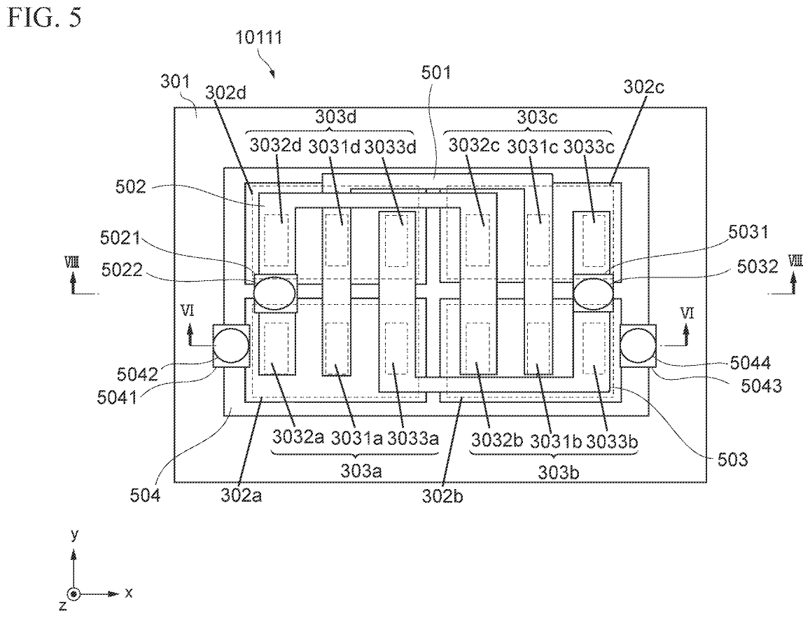

FIG. 5 is a layout diagram of the field effect transistor unit 10111. The field effect transistor unit 10111 includes four unit field effect transistors 303a, 303b, 303c, and 303d. Here, the number of unit field effect transistors included in the field effect transistor unit 10111 is not limited to four but may be greater or less than four.

Gate electrodes 3031a to 3031d of the respective unit field effect transistors 303a to 303d are connected with each other by gate wiring 501 having a comb shape.

Source regions 3032a to 3032d of the respective unit field effect transistors 303a to 303d are connected with each other by source wiring 502 having a comb shape.

Drain regions 3033a to 3033d of the respective unit field effect transistors 303a to 303d are connected with each other by drain wiring 503 having a comb shape.

Wiring 504 is provided on a z-axis positive direction side of the heat dissipation guard ring regions 305 (not shown) of the respective unit field effect transistors 303a to 303d. The wiring 504 is formed so as to surround each of the unit field effect transistors 303a to 303d.

A bump placement portion 5021 and a bump 5022 are provided on the z-axis positive direction side of the source wiring 502. The bump placement portion 5021 and the bump 5022 are metal members.

A bump placement portion 5031 and a bump 5032 are provided on the z-axis positive direction side of the drain wiring 503. The bump placement portion 5031 and the bump 5032 are metal members.

Bump placement portions 5041 and 5043 and bumps 5042 and 5044 are provided on the z-axis positive direction side of the wiring 504. The bump placement portions 5041 and 5043 and the bumps 5042 and 5044 are metal members.

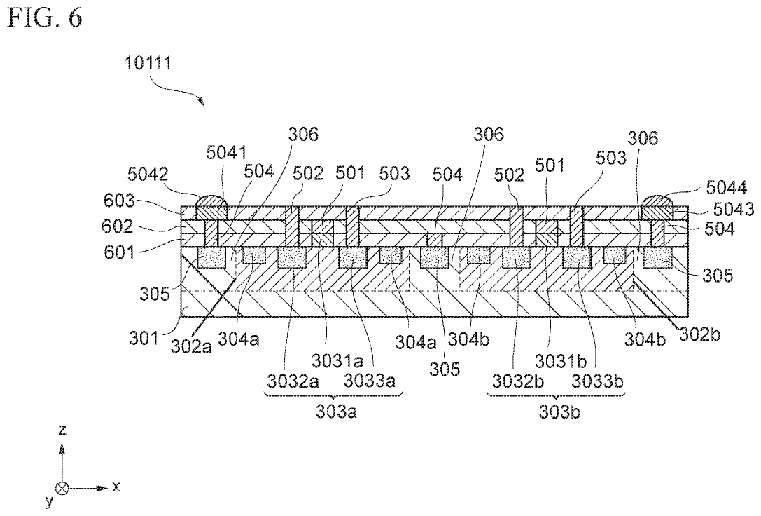

A cross sectional configuration of the field effect transistor unit 10111 including the unit field effect transistors 303a and 303b will be described with reference to FIG. 6.

The gate wiring 501, the source wiring 502, the drain wiring 503, and the wiring 504 are provided in wiring layers 601, 602, and 603 that are provided on the z-axis positive direction side, that is, in an upper portion of the semiconductor substrate 301.

The gate wiring 501 is provided in the wiring layer 602 so as to be positioned on the gate electrodes 3031a and 3031b.

The source wiring 502 is provided in the wiring layers 601, 602, and 603 so as to be positioned on the source regions 3032a and 3032b.

The drain wiring 503 is provided in the wiring layers 601, 602, and 603 so as to be positioned on the drain regions 3033a and 3033b.

The wiring 504 is provided in the wiring layers 601 and 602 so as to be positioned on the heat dissipation guard ring region 305.

The gate wiring 501, the source wiring 502, the drain wiring 503, and the wiring 504 in the wiring layers 601, 602, and 603 are insulated from each other by insulators.

The bump placement portion 5041 and the bump placement portion 5043 are provided in the wiring layer 603. The bump 5042 is provided on the bump placement portion 5041. The bump 5044 is provided on the bump placement portion 5043. That is, a metal portion (first metal portion) is provided on the heat dissipation guard ring region 305 in a manner to include the wiring 504, the bump placement portions 5041 and 5043, and the bumps 5042 and 5044.

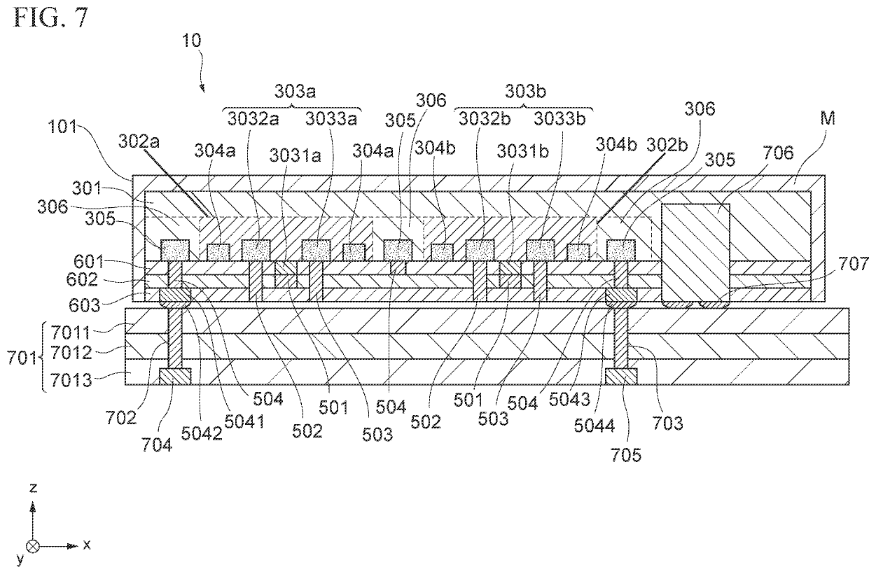

FIG. 7 is a sectional view of the semiconductor module 10 on which the semiconductor device 101 including the semiconductor substrate 301 is mounted via the bumps 5042 and 5044. In the semiconductor device 101, the semiconductor substrate 301 is molded with mold resin M. The semiconductor device 101 is mounted on a laminated substrate 701. The semiconductor device 101 includes the LDO circuit unit (first circuit unit) 1011 and another circuit unit (second circuit unit) such as the digital circuit unit 1012, for example. A circuit unit 706 provided in the semiconductor substrate 301 is a diagram schematically illustrating a circuit of the second circuit unit. The circuit unit 706 is connected to the laminated substrate 701 via a bump portion 707. On the semiconductor device 101, the LDO circuit unit (first circuit unit) 1011 including the unit field effect transistor 303, and other than the LDO circuit unit 1011, such as the digital circuit unit 1012, the reference circuit unit 1013, the logic circuit unit 1014, the bias control unit 1015, and the bias control unit 1016 are mounted.

The laminated substrate 701 includes substrate layers 7011, 7012, and 7013. Vias 702 and 703 are formed so as to extend in the z-axis direction of the laminated substrate 701. Electrodes 704 and 705 are provided as back electrodes in the substrate layer 7013, which is farthest from the semiconductor device 101. The via 702 is connected with the electrode 704 and the via 703 is connected with the electrode 705.

The via 702 is connected with the bump 5042 and the via 703 is connected with the bump 5044.

This allows heat conduction from the semiconductor device 101 toward the laminated substrate 701.

Heat dissipation in the semiconductor module 10 will be described with reference to FIG. 7. When the semiconductor module 10 is operated and a power source voltage is supplied to the semiconductor device 102 by the LDO circuit unit 1011, each of the unit field effect transistors 303a and 303b generates heat.

The heat generated by the unit field effect transistors 303a and 303b is conducted to surrounding members. At this time, the heat conducted to the z-axis positive direction side of the N wells 302a and 302b is conducted to the z-axis positive direction side of the semiconductor substrate 301. That is, part of the heat generated by the unit field effect transistors 303a and 303b is conducted to the vicinity of a surface, which is opposite to a surface closer to the laminated substrate 701, of the semiconductor substrate 301. The heat thus conducted travels through the P-type region of the semiconductor substrate 301 to the heat dissipation guard ring region 305.

The heat reaching the heat dissipation guard ring region 305 travels through the wiring 504, the bump placement portion 5041, and the bump 5042 toward the laminated substrate 701. Further, there is also a path of the heat traveling through the wiring 504, the bump placement portion 5043, and the bump 5044 toward the laminated substrate 701.

The heat reaching the bump 5042 is conducted to the via 702. The heat passes through the via 702 and reaches the electrode 704, then being dissipated to the outside. Heat is also dissipated through the bump 5044, the via 703, and the electrode 705. The heat dissipation property of the semiconductor substrate 301 can be thus improved.

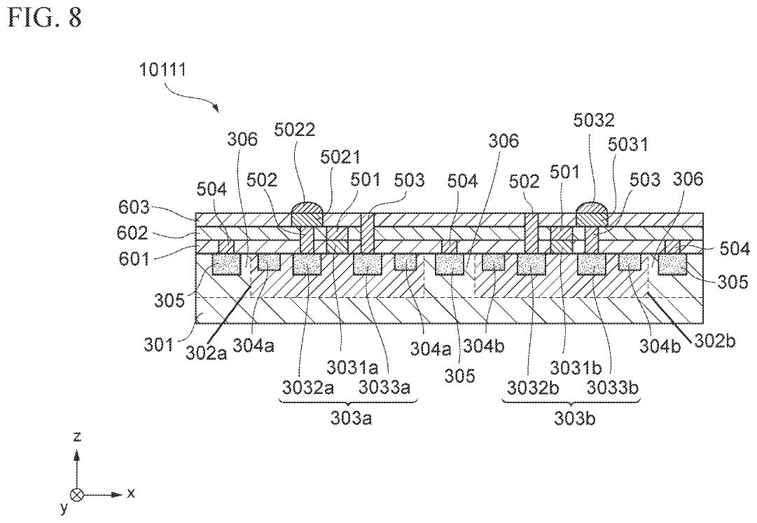

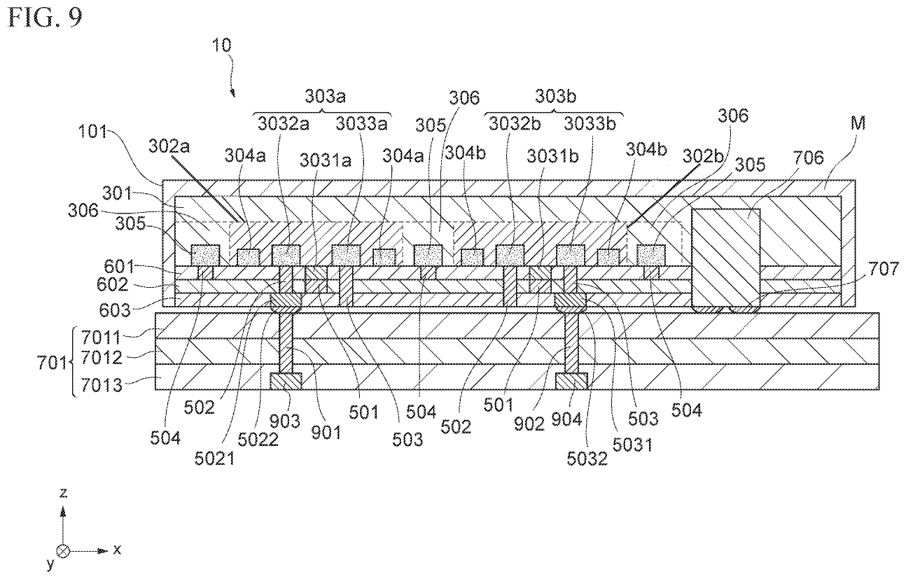

Heat dissipation by the bumps 5022 and 5032 will also be described with reference to FIGS. 8 and 9. FIG. 8 is a sectional view of the semiconductor substrate 301 on a cross section including the bump placement portions 5021 and 5031 and the bumps 5022 and 5032.

The bump placement portion 5021 and the bump placement portion 5031 are provided in the wiring layer 603. The bump 5022 is provided on the bump placement portion 5021. The bump 5032 is provided on the bump placement portion 5031. That is, a metal portion (second metal portion) is provided on the unit field effect transistor 303a so as to include the bump placement portion 5021 and the bump 5022.

FIG. 9 is a sectional view of the semiconductor module 10 provided with the semiconductor device 101 similarly to FIG. 7.

Vias 901 and 902 are formed along the z-axis direction of the laminated substrate 701. Electrodes 903 and 904 are provided as back electrodes in the substrate layer 7013, which is farthest from the semiconductor device 101. The via 901 is connected with the electrode 903 and the via 902 is connected with the electrode 904. The via 901 is connected with the bump 5022 and the via 902 is connected with the bump 5032.

In this configuration, part of heat generated by the unit field effect transistors 303a and 303b is dissipated through the source wiring 502, the bump placement portion 5021, the bump 5022, the via 901, and the electrode 903. Further, heat is also dissipated through the drain wiring 503, the bump placement portion 5031, the bump 5032, the via 902, and the electrode 904.

The semiconductor module 10 dissipates heat through the bumps 5022 and 5032 in addition to the heat dissipation through the bumps 5042 and 5044, being able to more efficiently dissipate heat generated by the LDO circuit unit 1011.

A second embodiment will be described. The second and following embodiments will omit the description of matters common to those of the first embodiment and describe only different points. In particular, the same advantageous effects obtained from the same configuration will not be sequentially mentioned in each embodiment.

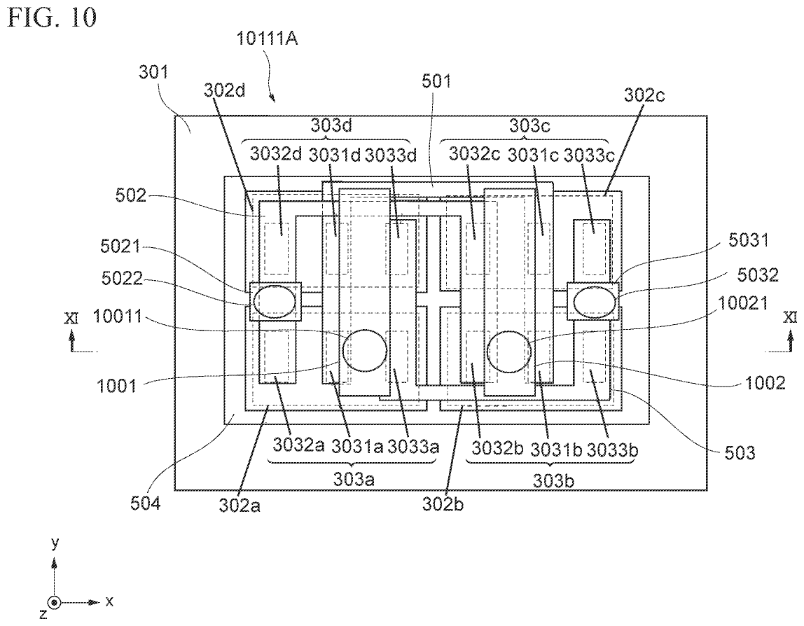

FIG. 10 is a layout diagram of a field effect transistor unit 10111A in a semiconductor device according to the second embodiment.

The field effect transistor unit 10111A is different from the field effect transistor unit 10111 in that wiring 1001 and wiring 1002 are provided on the z-axis positive direction side of the source wiring 502 and the drain wiring 503. The wiring 1001 and the wiring 1002 are provided on the inner side of each unit field effect transistor in plan view of the xy plane. A bump 10011 is provided on the wiring 1001. A bump 10021 is provided on the wiring 1002.

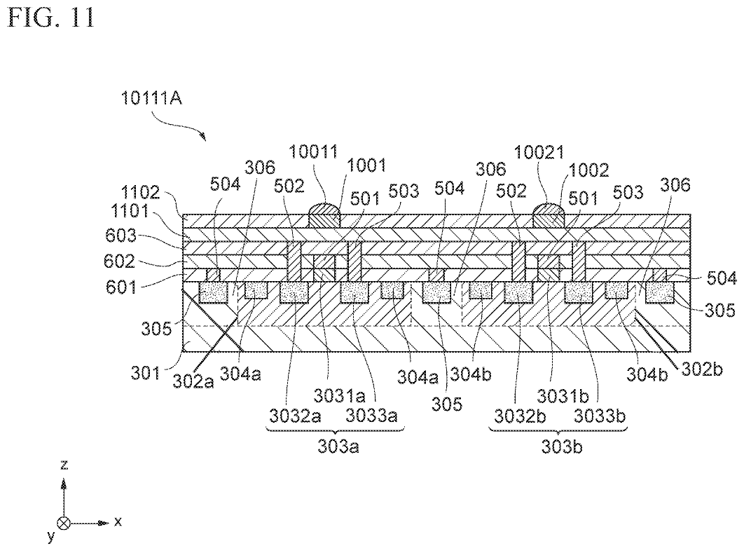

FIG. 11 is a sectional view of the field effect transistor unit 10111A. In the field effect transistor unit 10111A, an insulating layer 1101 and a wiring layer 1102 are provided on the wiring layer 603. The wiring 1001 and the wiring 1002 are provided in the wiring layer 1102. The bump 10011 is provided on the wiring 1001. The bump 10021 is provided on the wiring 1002.

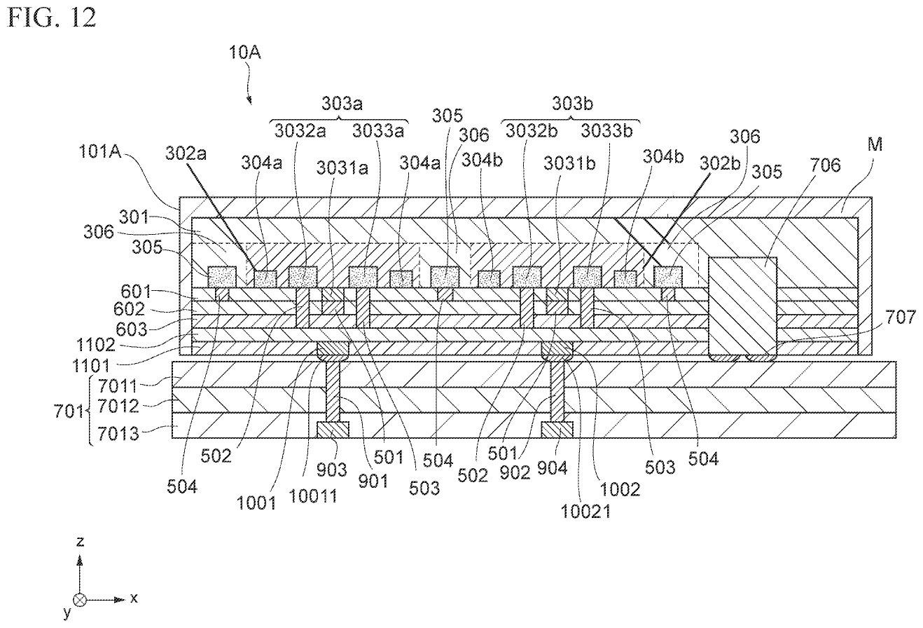

FIG. 12 is a sectional view of a semiconductor module 10A on which a semiconductor device 101A provided with the field effect transistor unit 10111A is mounted. In the semiconductor module 10A as well, heat can be dissipated through the bump 10011 and the bump 10021 in the same manner as described in the first embodiment regarding FIG. 9.

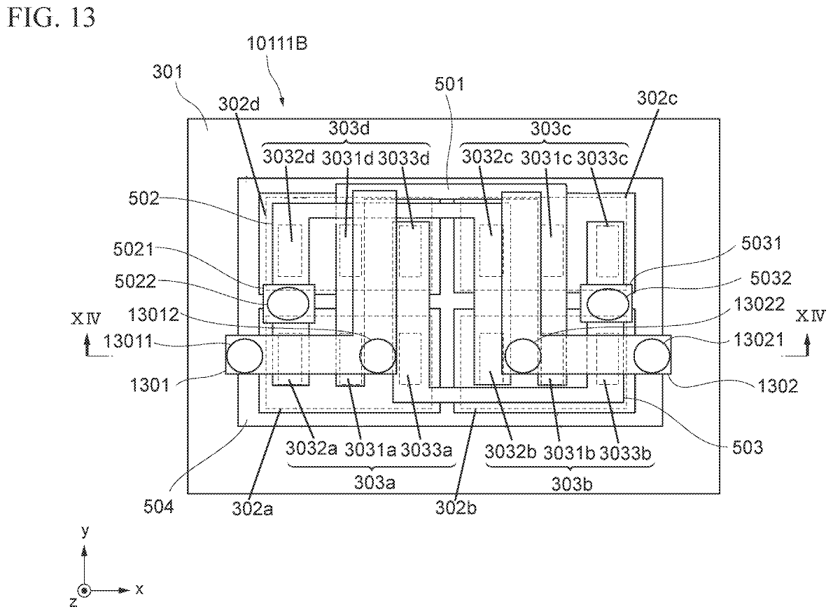

A third embodiment will be described. FIG. 13 is a layout diagram of a field effect transistor unit 10111B in a semiconductor device according to the third embodiment.

The field effect transistor unit 10111B is different from the field effect transistor unit 10111 in that pieces of wiring (third metal portion) 1301 and 1302 are provided on the z-axis positive direction side of the source wiring 502 and the drain wiring 503. Bumps 13011 and 13012 are provided on the wiring 1301. Bumps 13021 and 13022 are provided on the wiring 1302. The bumps 13011 and 13021 are provided so as to be positioned on the wiring 504.

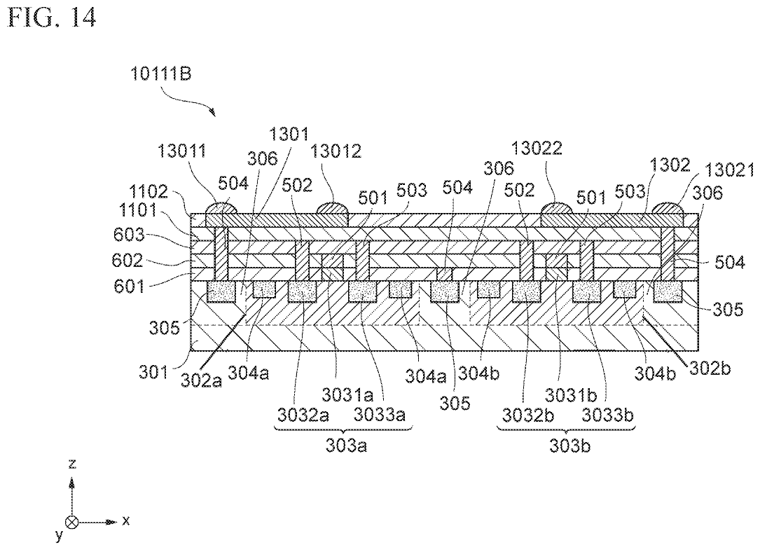

FIG. 14 is a sectional view of the field effect transistor unit 10111B. In the field effect transistor unit 10111B, the insulating layer 1101 and the wiring layer 1102 are provided on the wiring layer 603. The wiring 1301 and the wiring 1302 are provided in the wiring layer 1102. The bumps 13011 and 13012 are provided on the wiring 1301. The bumps 13021 and 13022 are provided on the wiring 1302.

In the field effect transistor unit 10111B, the wiring 504 is formed so as to connect the bump 13011 and the heat dissipation guard ring region 305 with each other. Further, the wiring 504 is formed so as to connect the bump 13021 and the heat dissipation guard ring region 305 with each other. The heat dissipation guard ring region 305 is connected to the bump 13012 via the wiring 504 and the wiring 1301. The heat dissipation guard ring region 305 is connected to the bump 13022 via the wiring 504 and the wiring 1302.

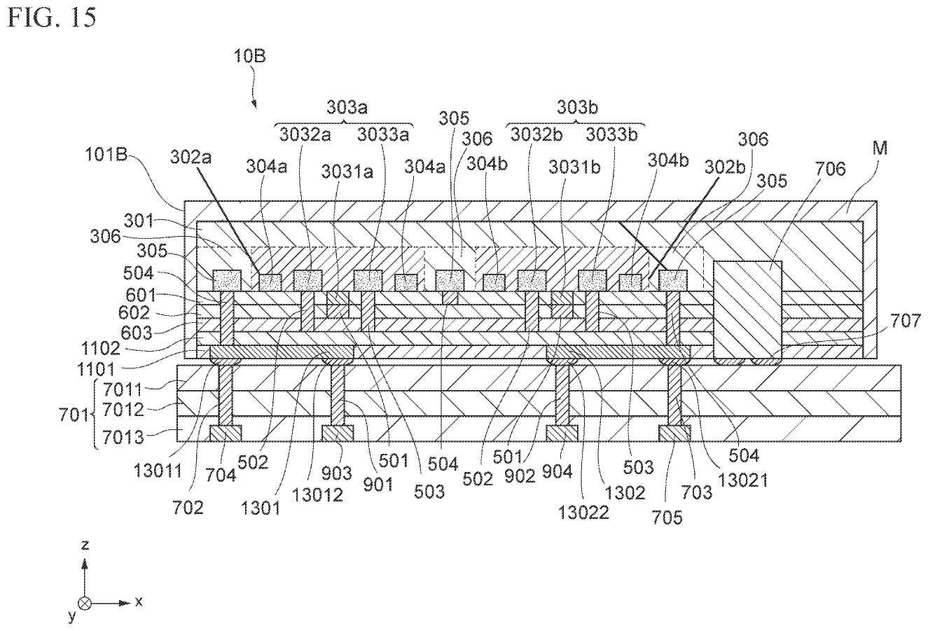

FIG. 15 is a sectional view of a semiconductor module 10B on which a semiconductor device 101B provided with the field effect transistor unit 10111B is mounted.

In the semiconductor module 10B, heat is dissipated through the wiring 504, the wiring 1301, the bump 13011, the via 702, and the electrode 704 in the same manner as described in the first embodiment regarding FIG. 7. Heat is also dissipated through the wiring 504, the wiring 1302, the bump 13021, the via 703, and the electrode 705.

In addition to the above-mentioned heat dissipation, heat that travels from the heat dissipation guard ring region 305 to the wiring 504 along the z-axis direction travels in the wiring 1301 along the xy plane, being conducted to the bump 13012, in the semiconductor module 10B. This heat is dissipated through the bump 13012, the via 901, and the electrode 903. Heat dissipation through the heat dissipation guard ring region 305 is thus facilitated. Heat dissipation through the wiring 1302 is also similarly facilitated.

Further, the semiconductor module 10B also has heat dissipation paths as those of the semiconductor module 10A and therefore, the semiconductor module 10B can more efficiently dissipate heat.

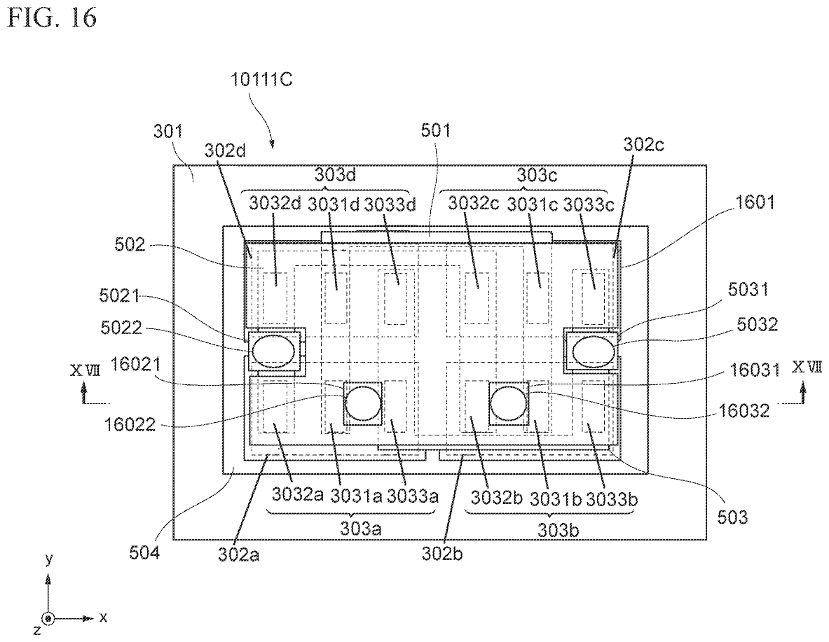

A fourth embodiment will be described. FIG. 16 is a layout diagram of a field effect transistor unit 10111C in a semiconductor device according to the fourth embodiment.

The field effect transistor unit 10111C is different from the field effect transistor unit 10111 in that rewiring (fourth metal portion) 1601 is provided on the z-axis positive direction side of the source wiring 502 and the drain wiring 503. The material of the rewiring 1601 may be, for example, a metal material having higher thermal conductivity than the metal material used for the gate wiring 501 and the like. For example, aluminum can be used for the gate wiring 501 and the like, and copper can be used for the rewiring 1601.

Bump placement portions 16021 and 16031 are provided on the rewiring 1601. A bump 16022 is provided on the bump placement portion 16021. A bump 16032 is provided on the bump placement portion 16031. The rewiring 1601 is, for example, a metal portion that is formed to have a larger area than those of the bump placement portions 16021 and 16031 and those of the bumps 16022 and 16032 in the xy plane.

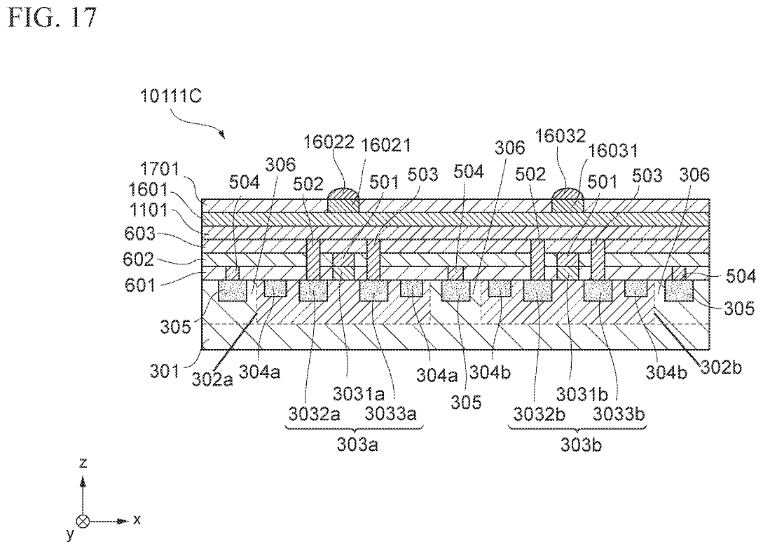

FIG. 17 is a sectional view of the field effect transistor unit 10111C. In the field effect transistor unit 10111C, the rewiring 1601 is provided on the insulating layer 1101. A wiring layer 1701 is provided on the rewiring 1601. The bump placement portions 16021 and 16031 are provided in the wiring 1701. The bump 16022 is provided on the bump placement portion 16021, and the bump 16032 is provided on the bump placement portion 16031.

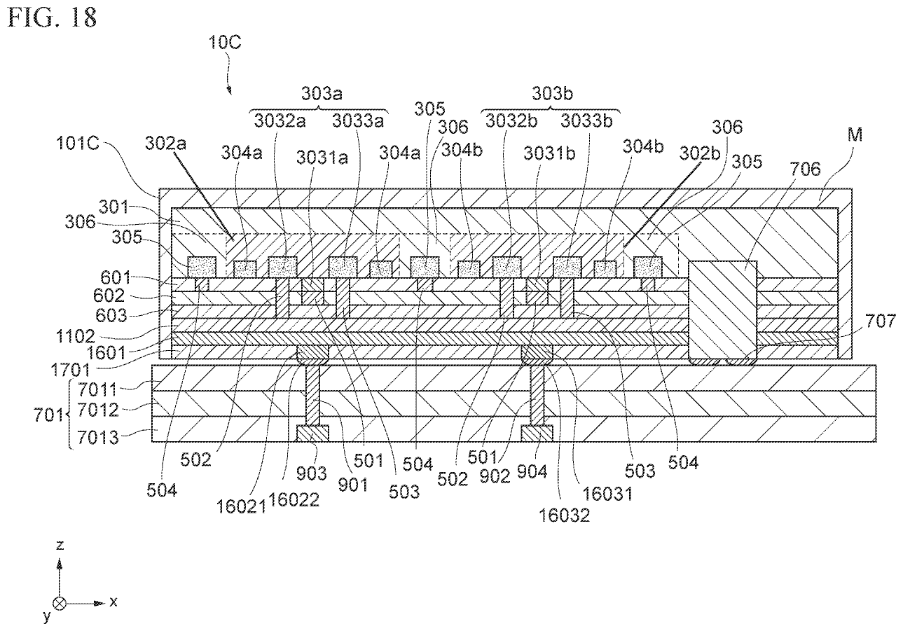

FIG. 18 is a sectional view of a semiconductor module 10C on which a semiconductor device 101C provided with the field effect transistor unit 10111C is mounted. In the semiconductor module 10C as well, heat can be dissipated through the bump 16022 and the bump 16032 in the same manner as described in the first embodiment regarding FIG. 9.

Part of heat generated by the unit field effect transistors 303a and 303b is conducted to the rewiring 1601 in the semiconductor module 10C. The heat conducted to the rewiring 1601 is dissipated through the bumps 16022 and 16032. Thus, heat is collected and dissipated from a wider area than in the configuration illustrated in FIG. 12, realizing effective heat dissipation. Further, heat can also be dissipated through paths, other than the bumps 16022 and 16032, from the rewiring 1601 toward the laminated substrate 701, realizing effective heat dissipation.

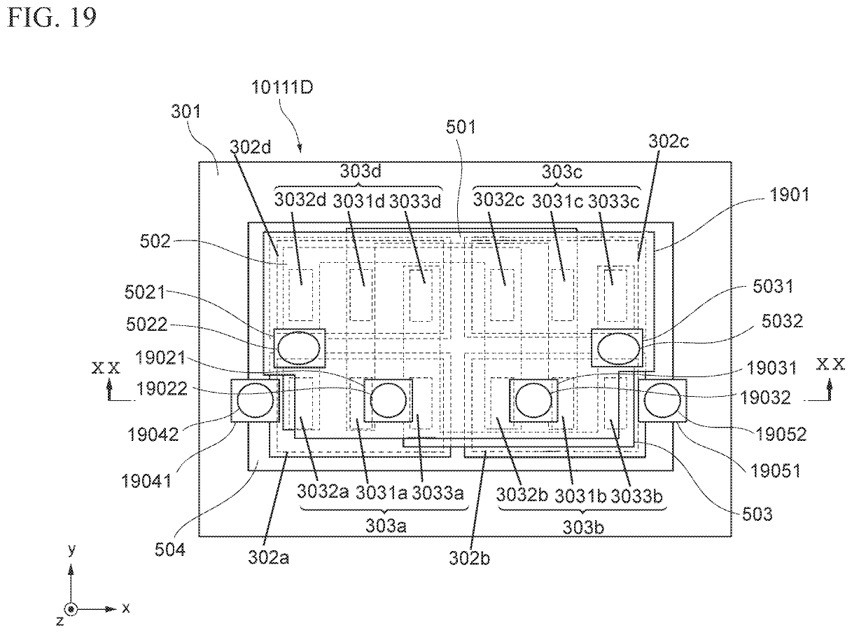

A fifth embodiment will be described. FIG. 19 is a layout diagram of a field effect transistor unit 10111D in a semiconductor device according to the fifth embodiment.

The field effect transistor unit 10111D is different from the field effect transistor unit 10111 in that rewiring 1901 is provided on the z-axis positive direction side of the source wiring 502 and the drain wiring 503. The material of the rewiring 1901 can be appropriately changed as is the case with the rewiring 1601.

Bump placement portions 19021 and 19031 are provided on the rewiring 1901. The bump placement portions 19021 and 19031 are connected to the rewiring 1901. A bump 19022 is provided on the bump placement portion 19021. A bump 19032 is provided on the bump placement portion 19031.

The rewiring 1901 is, for example, a metal portion that is formed to have a larger area than those of the bump placement portions 19021 and 19031 and those of the bumps 19022 and 19032 in the xy plane.

Bump placement portions 19041 and 19051 are provided on the wiring 504. A bump 19042 is provided on the bump placement portion 19041. A bump 19052 is provided on the bump placement portion 19051.

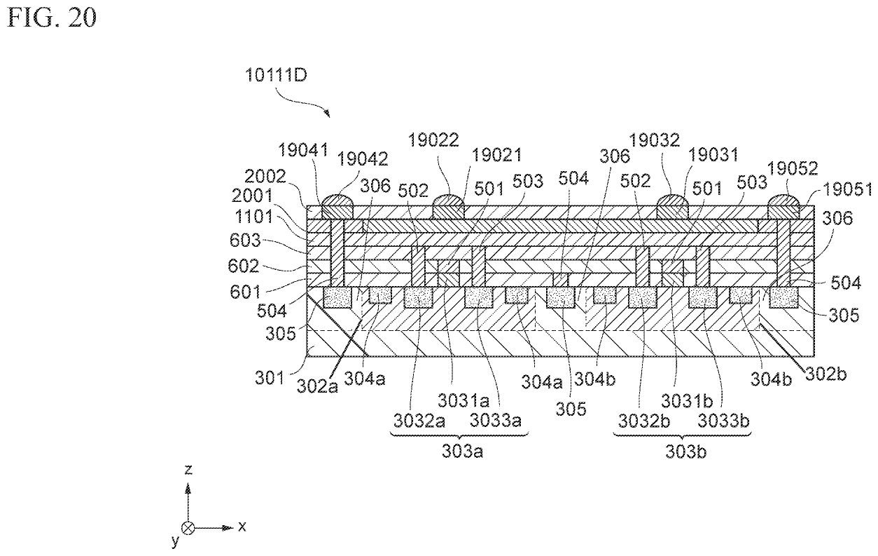

FIG. 20 is a sectional view of the field effect transistor unit 10111D. In the field effect transistor unit 10111D, a wiring layer 2001 is provided on the insulating layer 1101. A wiring layer 2002 is provided on the wiring layer 2001. The rewiring 1901 is provided in the wiring layer 2001. The bump placement portions 19021, 19031, 19041, and 19051 are provided in the wiring layer 2002. The bump 19022 is provided on the bump placement portion 19021, the bump 19032 is provided on the bump placement portion 19031, the bump 19042 is provided on the bump placement portion 19041, and the bump 19052 is provided on the bump placement portion 19051.

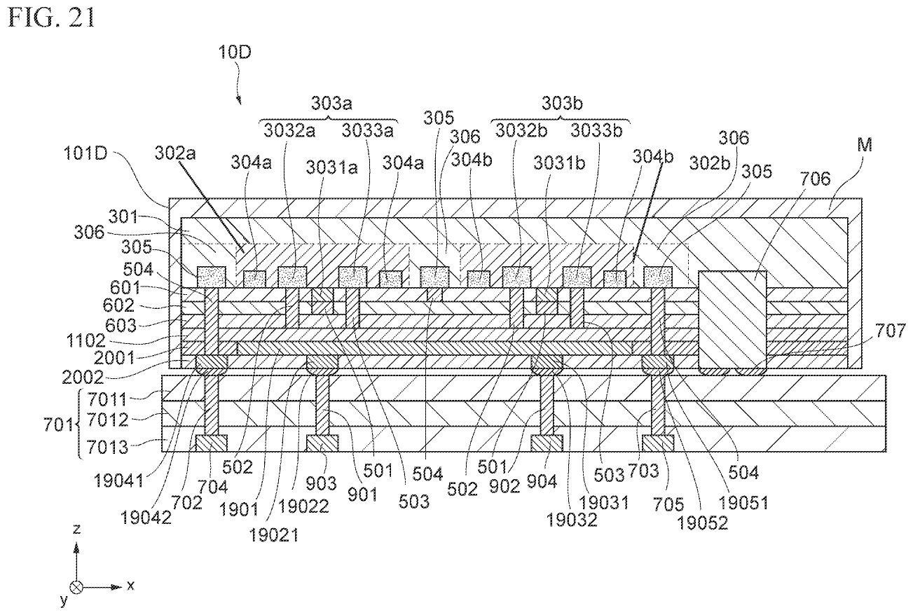

FIG. 21 is a sectional view of a semiconductor module 10D on which a semiconductor device 101D provided with the field effect transistor unit 10111D is mounted. In the semiconductor module 10D as well, heat can be dissipated through the bump 19022 and the bump 19032 in the same manner as described in the fourth embodiment regarding FIG. 18.

Further, in the semiconductor module 10D, heat can be further dissipated through the bumps 19042 and 19052 in the same manner as described in the first embodiment regarding FIG. 7. This allows efficient heat dissipation. When the rewiring 1901 is arranged so as to be positioned in the vicinity of the bump placement portion 19041 and the bump 19042, heat conducted through the rewiring 1901 can travel to the bump placement portion 19041 and the bump 19042 to be dissipated. This also allows efficient heat dissipation.

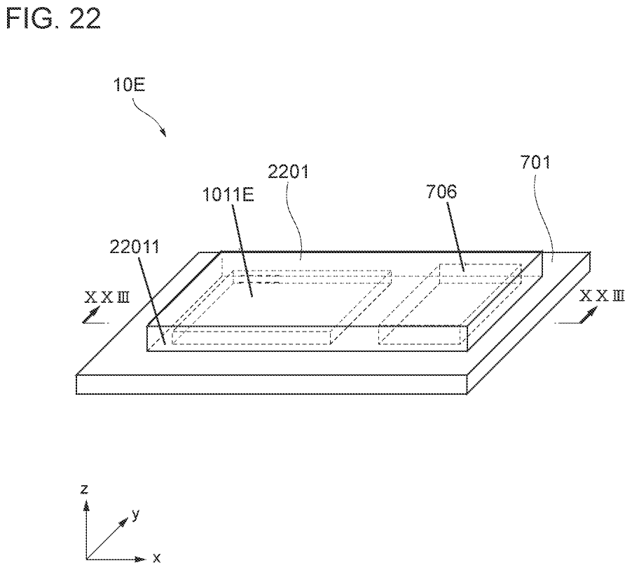

A sixth embodiment will be described. FIG. 22 is a schematic perspective view of a semiconductor module 10E according to the sixth embodiment.

In a semiconductor device of the semiconductor module 10E, a heat dissipation member 2201 is provided so as to cover an LDO circuit unit 1011E, including a field effect transistor, and the circuit unit 706. The heat dissipation member 2201 has an opening 22011 on the laminated substrate 701 side. The LDO circuit unit 1011E is connected to the laminated substrate 701 through the opening 22011. The heat dissipation member 2201 is, for example, a metal material.

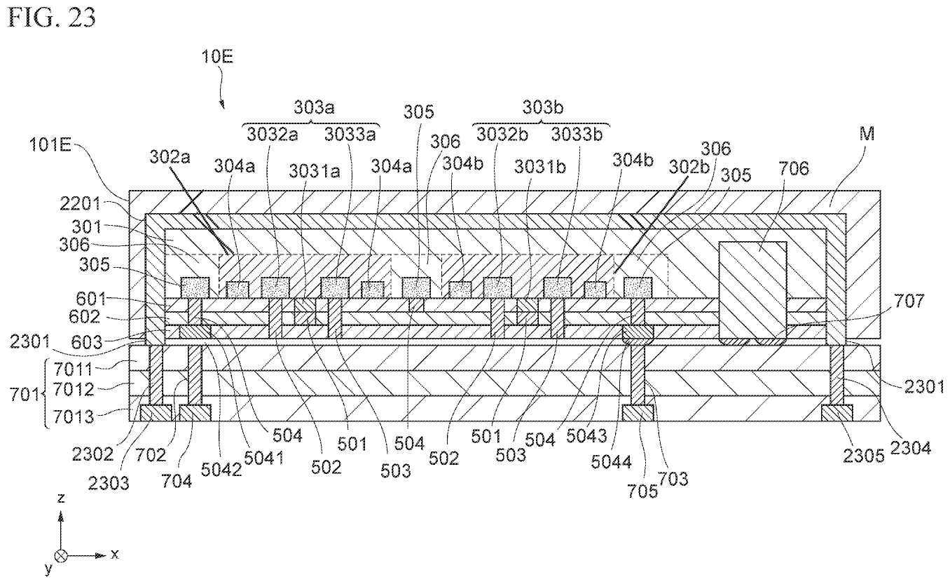

FIG. 23 is a sectional view of the semiconductor module 10E. FIG. 23 illustrates a sectional view of a state in which a semiconductor device 101E including the heat dissipation member 2201 is mounted on the laminated substrate 701.

Vias 2302 and 2304 are formed along the z-axis direction of the laminated substrate 701 in the semiconductor module 10E. Electrodes 2303 and 2305 are provided as back electrodes in the substrate layer 7013. The via 2302 is connected with the electrode 2303 and the via 2304 is connected with the electrode 2305. Each of the vias 2302 and 2304 is connected with the heat dissipation member 2201 through an end portion 2301 of the heat dissipation member 2201.

In the semiconductor module 10E, heat can be dissipated through the bumps 5042 and 5044 in the same manner as described in the first embodiment regarding FIG. 7.

Further, heat that is conducted to the upper portions of the unit field effect transistors 303a and 303b and is accumulated in the semiconductor substrate 301 can travel through the heat dissipation member 2201 toward the laminated substrate 701. The heat traveling the heat dissipation member 2201 is transferred to the via 2302 and the electrode 2303 through the end portion 2301, being dissipated to the outside of the semiconductor module 10E. The heat is also dissipated through the via 2304 and the electrode 2305 from the heat dissipation member 2201. The heat can be thus efficiently dissipated. Here, it is enough that the heat dissipation member 2201 is provided to cover the unit field effect transistor 303, and the heat dissipation member is not necessarily provided to cover the circuit unit 706.

The exemplary embodiments of the present disclosure have been described thus far. The semiconductor device 101 according to the first embodiment includes: the P-type semiconductor substrate 301, which has the main surface 401 and the main surface 402 opposed to the main surface 401; the N-type N well 302, which is provided on the main surface 401 side of the semiconductor substrate 301; the unit field effect transistor 303, which is provided in the N well 302; the P-type heat dissipation guard ring region 305, which is provided on the main surface 401 side of the semiconductor substrate 301 on the outside of the N well in plan view of the semiconductor substrate 301; the wiring 504, which is provided on the heat dissipation guard ring region 305; the bump placement portions 5041 and 5043; and the bumps 5042 and 5044.

In heat generated by the unit field effect transistor 303, heat conducted to the main surface 402 side of the N well 302 is conducted through the P-type semiconductor substrate 301 to the heat dissipation guard ring region 305 on the main surface 401 side, in the semiconductor substrate 301. This heat is dissipated to the outside of the semiconductor device 101 through the wiring 504 which is provided on the heat dissipation guard ring region 305, the bump placement portions 5041 and 5043, and the bumps 5042 and 5044. Thus, the semiconductor device 101 dissipates heat on the main surface 402 side, which is an opposite side to the main surface 401 side closer to the unit field effect transistor 303. The heat dissipation property in the semiconductor substrate can be thus improved.

The semiconductor device 101 further includes the bump placement portions 5021 and 5031 and bumps 5022 and 5032, which are provided on the unit field effect transistor 303. Accordingly, the semiconductor device 101 can further dissipate heat through the bumps 5022 and 5032. This can improve the heat dissipation property in the semiconductor substrate.

The semiconductor device 101B further includes the wiring 1301, which connects the wiring 504 with the bump 13012, and the wiring 1302, which connects the wiring 504 with the bump 13022, in the direction along the main surface 401. Accordingly, heat from the heat dissipation guard ring region 305 is dissipated from more bumps through the wiring 504. The heat dissipation property in the semiconductor substrate can be thus improved.

The semiconductor device 101D further includes the rewiring 1901 that is provided between the bump 19022 and the unit field effect transistor 303 in a manner to be connected with the bump 19022 and that has a larger area than the bump 19022 in plan view of the semiconductor substrate 301. Accordingly, the rewiring 1901 can collect heat from a wider range than the bump 19032. The semiconductor device 101D dissipates the heat through the bump 19032, realizing efficient heat dissipation.

The semiconductor device 101 further includes the LDO circuit unit 1011, which includes the unit field effect transistor 303, and the circuit unit 706, which does not include the unit field effect transistor 303. Accordingly, when the semiconductor device 101 is mounted on, for example, a laminated substrate, a heat-dissipation area is increased by the area of the circuit unit 706. This improves the heat dissipation property in the semiconductor substrate.

Further, the semiconductor module 10 includes the semiconductor device 101 and the laminated substrate 701, which includes the vias 702 and 703 which are connected with the bumps 5042 and 5044. This realizes heat dissipation through the vias 702 and 703. Accordingly, the heat dissipation property of the semiconductor module 10 is improved.

The semiconductor module 10E further includes the heat dissipation member 2201 that has the opening 22011 on the laminated substrate 701 and is provided so as to cover the unit field effect transistor 303 in the LDO circuit unit (first circuit unit) 1011 and another circuit unit (second circuit unit) 706. The laminated substrate 701 has the vias 2302 and 2304, which are connected to the end portion 2301 on the laminated substrate 701 side of the heat dissipation member 2201. Accordingly, part of heat from the unit field effect transistor 303 travels through the heat dissipation member 2201. This heat passes through the end portion 2301 and is dissipated through the via 2302 and the electrode 2303. Heat generated by the unit field effect transistor 303 is thus dissipated to the outside of the semiconductor module 10E. Consequently, the heat dissipation property of the semiconductor module 10E is improved.

It should be noted that each of the embodiments described above is provided for facilitating the understanding of the present disclosure, and is not provided for limiting the interpretation of the present disclosure. The present disclosure can be modified/improved without departing from the spirit thereof, and the present disclosure also includes an equivalent thereof. That is, each embodiment whose design is appropriately changed by those skilled in the art is also included in the scope of the present disclosure as long as the embodiment has the features of the present disclosure. For example, elements included in each embodiment and their arrangement, material, condition, shape, size, and the like are not limited to those exemplified, and can be appropriately changed. Further, it goes without saying that each of the embodiments is exemplary and partial substitution or combination of the configurations described in different embodiments can be performed, and this is also included in the scope of the present disclosure as long as the features of the present disclosure are included.

### REFERENCE SIGNS LIST

10, 10A, 10B, 10C, 10D, 10E semiconductor module
101, 101A, 101B, 101C, 101D, 101E semiconductor device
301 semiconductor substrate
302 N well
303 unit field effect transistor
305 heat dissipation guard ring region
306 P well
504 wiring
5042, 5044 bump

1. A semiconductor device comprising:
a semiconductor substrate that is of a first conductive type and that has a first main surface and a second main surface opposed to the first main surface;
a first well that is of a second conductive type and that is on a first main surface side of the semiconductor substrate;
a field effect transistor that is in the first well;
a second well that is of the first conductive type, that is on the first main surface side of the semiconductor substrate, and that is outside of the first well in a plan view of the semiconductor substrate; and
a first metal portion that is on the second well.

2. The semiconductor device according to claim 1, further comprising:
a second metal portion that is on the field effect transistor.

3. The semiconductor device according to claim 2, further comprising:
a third metal portion that connects the first metal portion and the second metal portion with each other, in a direction along the first main surface.

4. The semiconductor device according to claim 2, further comprising:
a fourth metal portion that is between the second metal portion and the field effect transistor, that is connected with the second metal portion, and that has a larger area than the second metal portion in the plan view of the semiconductor substrate.

5. The semiconductor device according to claim 1, further comprising:
a first circuit that comprises the field effect transistor; and
a second circuit that does not comprise the field effect transistor.

6. A semiconductor module comprising:
the semiconductor device according to claim 1; and
a laminated substrate that has a via connected with the metal portion.

7. The semiconductor module according to claim 6, further comprising:
a heat dissipation member that has an opening on a laminated substrate side of the semiconductor module, and that covers the field effect transistor,
wherein the laminated substrate has a via that is connected with an end portion on the laminated substrate side of the heat dissipation member.

8. The semiconductor module according to claim 7, wherein the heat dissipation member is a metal material.

9. The semiconductor device according to claim 1, wherein the first conductive type is a P-type conductive property, and the second conductive type is an N-type conductive property.
